(19) United States
(12) Patent Application Publication
(10) Pub. No.: US 2011/0199830 A1
(43) Pub. Date: Aug. 18, 2011

(54) FLOTOX-BASED, BIT-ALTERABLE, COMBO FLASH AND EEPROM MEMORY

(76) Inventors: Peter Wung Lee, Saratoga, CA (US); Fu-Chang Hsu, San Jose, CA (US)

(21) Appl. No.: 13/015,579

(22) Filed: Jan. 28, 2011

Related U.S. Application Data
(60) Provisional application No. 61/337,991, filed on Feb. 12, 2010.

(51) Int. Cl. G11C 16/10; G11C 16/16

(52) U.S. Cl. 365/185.18; 365/185.33

(57) ABSTRACT

A non-volatile memory array having FLOTOX-based memory cells connected by a plurality of word lines and a plurality of bit lines is disclosed. In the memory array, the FLOTOX-based memory cells in a common word line do not share a common source line. Instead, the FLOTOX-based memory cells associated with a bit line are provided with a source line laid out in parallel with the bit line to avoid punch-through leakage. The FLOTOX-based memory cells may be 2T FLOTOX-based EEPROM cells or 1T FLOTOX-based flash cells. The byte-alterable and page-alterable functions of a 2T EEPROM array and the block-alterable function of a 1T flash array are preserved. In addition, a novel bit-alterable function is added to both 2T FLOTOX-based EEPROM array and 1T FLOTOX-based flash array to reduce the unnecessary high voltage over-stress in a write operation to improve program/erasure endurance cycles.

### CROSS-REFERENCE TO RELATED APPLICATIONS

This application claims priority under 35 U.S.C. §119 to U.S. Provisional Patent Application Ser. No. 61/337,991, filed on Feb. 12, 2010, assigned to the same assignee as the present invention, and incorporated herein by reference in its entirety.

### RELATED PATENT APPLICATIONS

U.S. Provisional Patent Application Ser. No. 61/126,854, filed on May 7, 2008, assigned to the same assignee as the present invention, and incorporated herein by reference in its entirety.

U.S. Provisional Patent Application Ser. No. 61/130,381, filed on May 30, 2008, assigned to the same assignee as the present invention, and incorporated herein by reference in its entirety.

### BACKGROUND OF THE INVENTION

1. Field of the Invention

This invention relates generally to nonvolatile memory circuits, devices, and methods of operation. More particularly, this invention relates to floating gate tunneling oxide based (FLOTOX-based) nonvolatile memory circuits, devices, and methods of operation.

2. Description of Related Art

FIG. 1A shows a conventional two-transistor (2T) FLOTOX-based electrically erasable programmable read only memory (EEPROM) cell. The basic structure of the 2T EEPROM cell is a 2T storage cell that comprises one select transistor (ST) made of a single-poly high voltage (HV) thick-oxide-gate NMOS transistor that has no storage function and one floating-gate transistor (FT) made of a double-poly floating-gate NMOS transistor that provides the major storage function of the EEPROM cell. The drain of ST is connected to a bit line (BL) and the source, denoted as B, is connected in series with the drain of FT. The source of FT is normally connected to a source line (SL). The SL is always connected to a power supply voltage VSS in a traditional EEPROM array. The gate of ST is connected to SWL that is coupled to the output of a select decoder, while the gate of FT is connected to FWL that is coupled to the output of a byte-select transistor.

The 2T EEPROM cell shown in FIG. 1A has four electric terminals that are generally denoted according to the electrical signal lines connected to them, including a drain node BL, a select gate SWL, a control gate FWL, and a source node SL. FIG. 1C shows the cross-sectional view of the device structure of the FLOTOX-based EEPROM cell of FIG. 1A. As shown in FIG. 1C, the common bulk terminal of both NMOS ST and NMOS FT devices is formed over a common bulk of P-substrate which is usually coupled to the voltage VSS. Electrically, ST functions as a BL switch device and FT functions as a nonvolatile memory (NVM) storage device that retains data even after an external power supply has been cut off.

Conventionally, the process of forming the ST device can be either a Poly1-gate transistor or a Poly2-gate transistor, depending on the preference of a specific FLOTOX manufacturing process. The FT NVM storage device is a stacked-gate device formed with a Poly1-floating-gate and a Poly2-gate on top. As shown in FIG. 1C, the Poly1-floating-gate, which is formed over the thick-gate-oxide above the channel region and the thin-tunnel-oxide above the drain, is not accessible. Both Poly1 and Poly2 layers are conductive layers. Poly1 layer is used for storing electrons to allow the threshold voltage (Vt) adjustment of each FT storage transistor. Both drain and source of each FT are doped with N-plus impurity and formed over the P-substrate.

The double-poly stacked-gate FT transistor is an asymmetrical transistor. As seen in FIG. 1C, the drain of FT, denoted by B, extends over the thin-tunnel-gate region with a great enclosure, while the source, denoted by SL, also doped with N-plus is located at the leftmost end of the double-poly thick-gate transistor. The tunnel-oxide region at the drain is surrounded by a safe enclosure to guarantee a high-quality Fowler-Nordheim (FN) channel erasure and program to meet the specification of 1M endurance cycles.

The Poly1-floating-gate layer of FT is used to store a plurality of electron negative charges that can flexibly alter the Vt of the EEPROM cell. Because of the FN tunneling effect on an EEPROM cell in an erasure operation, more electrons are injected into the Poly1-floating-gate layer of the FT device to result in the increase of the Vt of the EEPROM cell to a higher value VtH, which is typically referred to as a non-conduction state for storing “1” binary data. VtH is usually set at an optimized value of +2.0V with excessive electrons on the floating-gate. To the contrary, in a program operation, electrons are expelled out of the floating-gate with excessive positive charges being left on the floating-gate to decrease the Vt of the EEPROM cell to a lower value VtL, which is referred to as a conduction state for storing “0” binary data. A typical value of VtL is −2.0V.

As can be seen from the cross-sectional view in FIG. 1C with a closer look into the conventional 2T FLOTOX-based EEPROM cell, the true equivalent electric circuit of the EEPROM cell as illustrated in FIG. 1B shows a three-transistor (3T) device, comprising a ST as described above in series with a FT which is a virtual 2T device. The FT device is virtually comprised of two double-Poly gate transistors FTa and FTb connected in series and sharing the same Poly1 floating-gate layer and the same Poly2 control-gate layer. As shown in FIG. 1B, the source, denoted by B2, of FTa is connected to the drain of FTb. The source of FTb is denoted by SL. As shown in FIG. 1C, a buried N-plus layer BN+ is intently designed to surround the thin tunnel-oxide area with a big enclosure near the drain of FT for performing high-quality FN channel erasure.

With reference to FIG. 1B, the FTa device in the middle of the EEPROM cell is electrically and physically sandwiched by two select transistors, ST and FTb. In reality, nodes B1 and B2 shown in FIG. 1B are shorted by the BN+ layer below the thin tunneling oxide. The channel lengths of both ST and FTb are very critical and have to be designed to prevent HV (+16.0V) punch-through during the program operation. Low-current FN program and FN erasure operations can only be carried out at the channel of FTa which has a thin tunneling oxide layer. FTb of each FT has a thick gate oxide layer and is used to prevent the program voltage +16.0V in the channel region of FTa from leaking to the SL node to guarantee the success of the FN channel program operation. In a program operation, the BLs of the selected cells to be programmed are coupled to 16.0V to induce the FN tunneling effect of the FTa devices. For those unselected cells in the selected byte, the BLs are coupled to 0V or a floating voltage to avoid inducing any FN effect on the unselected FTa devices.

FIG. 1D shows an exemplary circuit of two bytes 60, 70 of a conventional 2T FLOTOX-based EEPROM cell array 100. A typical byte of a 2T FLOTOX-based EEPROM cell array comprises eight 2T FLOTOX-based EEPROM cells 50 shown in FIG. 1A. The select transistors and floating-gate transistors in byte 70 are denoted as ST0-ST7 and FT0-FT7 respectively. Each byte comprises eight separate vertical metal bit lines, denoted as BL0-BL7, connected to the eight corresponding drains of the eight ST transistors, and the eight source nodes of the EEPROM cells are grouped to share a common horizontal source line SL0. The common horizontal source line SL0 is formed by the N-plus active layer and shared by bytes 60 and 70.

The gates of the eight ST transistors of byte 70 are connected together to the select word line SWL0, and the gates of the eight ST transistor of byte 60 are connected together to the select word line SWL1. The control gates of the eight FT transistors of byte 70 are connected together as FWL0, and the control gates of the eight FT transistor of byte 60 are connected together as FWL1. A HV single-poly NMOS transistor denoted as FWLT0 couples byte 70 to a gated byte line FGBL by connecting the gate, the drain and the source of FWLT0 to SWL0, FGBL and FWL0 respectively. Similarly, another HV single-poly NMOS transistor denoted as FWLT1 couples byte 60 to the gated byte line FGBL by connecting the gate, the drain and the source of FWLT1 to SWL1, FGBL and FWL1 respectively. Both FWL0 and FWL1 are Poly2 gate lines.

FIG. 1D shows only two bytes of a conventional 2T FLOTOX-based EEPROM cell array. Normally, a typical 1 Mb EEPROM array comprises 1K word lines such as SWL0-SWL1023, and 1K bit lines BL0-BL1023 of 128 bytes BYTE0-BYTE127 are grouped into 128×8 BLs such as BL0-BL7. Each word line connects to a total of 128 gates of 128 FWLTs of 128 bytes of 2T FLOTOX-based EEPROM cells with sources connecting to a respective source line such as SL0.

Assuming a selected byte for a byte-alterable write operation is the first byte 70 of the first word line in a 1 Mb 2T FLOTOX-based EEPROM cell array as shown in FIG. 1D. A byte-write operation involves two sub-steps including a first sub-step of a byte-erasure operation and a second sub-step of a byte-program operation. The two sub-steps are automatically controlled by an on-chip state machine in the EEPROM memory design. The byte-erasure operation is performed on a single byte basis, while the byte-program operation is performed on a bit-by-bit basis. One option in performing the desired byte-erasure and byte-program of a byte-write operation is done with a longer pulse time so that the need of any erase-verify and program-verify sub-steps can be eliminated to simplify the whole process of a byte-write operation, thus reducing the complexity of the on-chip state machine design.

In this example, the first byte in the first word line in the 1 Mb EEPROM array is selected for a detailed description of the byte-write operation. During a byte-erasure operation, a preferable set of voltage conditions is applied to the selected byte 70, which comprises the eight bit lines BL0-BL7, the gated byte line FGBL, the word line FWL0 and its associated SWL0. A preferable HV of 16 volts is applied to both FGBL and SWL0, and the bit lines BL0-BL7 are coupled to 0V. Because the Vt of the HV NMOS transistor FWLT0 is around −0.7V, FWLT0 is turned on by the 16.0V of SWL0 to pass its drain node voltage of 16.0V from FGBL to its source node, which is coupled to FWL0. All 1024 bit lines BL0-BL1023 are coupled to 0V, regardless of the selected first byte or the remaining unselected 127 bytes in the same SWL0 of any rows or pages.

In addition, the rest of the unselected 1023 word lines are also coupled to ground. As a result, a voltage of (16.0V-Vt) is passed to FWL0, where Vt is the threshold voltage of the HV NMOS device FWLT0. If FWLT0 is a native NMOS device, Vt is near 0V and FWL0 voltage is about +160.0V without drop from FGBL to the gates of the eight selected cells FT0-FT7 of the first selected byte along with 0V in the channel regions of the eight selected FTa transistors coupled from the grounded BL0-BL7 respectively. The rest of 127 FWL0 in the remaining 127 bytes sharing the same SWL0 would be grounded. Therefore, only the first byte of the first word line carries out the FN erasure operation.

Because the eight selected FT transistors have the same 16.0V gate voltage with their FTa channel regions at 0V, electrons are attracted to the floating gates of the FT devices and the Vt of the FT transistors are increased to VtH after a pre-determined byte-erasure time. Normally, the erasure time is less than 1 ms and the desired erased Vt voltage, i.e., VtH, is set at +2.0V. After a byte-erasure operation is carried out successfully on FT0-FT7 of the eight selected EEPROM cells in the first selected byte gated by FTWL0 in the first word line, each Vt of FT0-FT7 should be erased to the same value of +2.0V, regardless whether the initial Vt is VtH or VtL.

With a deep erasure operation under a longer pulse width, the erase-verify step can be skipped to simplify the byte-erasure step and flow, and therefore a simpler algorithm of an on-chip state-machine design can be adopted to save silicon area and erasure time. If the FWLT device is a HV Enhancement NMOS device, then the Vt would be around 0.7V to 1.0V, and FWL0 voltage would be around +15.0V, which may not be high enough to erase Vt to +2.0V in 1 ms. Thus, the FWLT device is preferable made of a native HV NMOS device for a negligible Vt drop on FWL0 for a reliable erasure and program operation.

During a byte-program operation on the same selected first byte, another preferable set of voltage conditions has to be applied to the selected byte assuming that the selected first byte has been erased successfully in the byte-erasure operation and is now to be performed with byte-program operation automatically controlled by the on-chip state machine. In the byte-program operation, the preferable HV of 16 volts is only applied to SWL0, FGBL is set to 0V but BL0-BL7 are coupled differently with either 16.0V or 0V, depending on the desired program data of the respective bits. For example, if a checkerboard write data pattern of 01010101 in the order of BL0 to BL7, is desired for the selected byte, the voltage applied to the respective bit lines of the selected first byte would be BL0=16V, BL1=0V, BL2=16V, BL3=0V, BL4=16V, BL5=0V, BL6=16V and BL7=0V. The rest of BL0-BL7 in the remaining 127 bytes and 1023 unselected word lines of the 1 Mb 2T FLOTOX-based EEPROM array are all grounded for the unselected byte-program operation of this example.

With the voltage conditions, the gates of FT0-FT7 of the selected first byte are grounded like the eight FT devices in the remaining 127 bytes of SWL0 of EEPROM cells, but the channel regions of the four FTa transistors in the selected first byte are coupled to about 15V. In this example, the selected channel regions belong to FT0, FT2, FT4 and FT6 and are coupled to 16.0V from BL0, BL2, BL4 and BL6 in the selected first byte. The channel regions of FT1, FT3, FT5 and FT7 are biased at 0V due to the grounded BL1, BL3, BL5 and BL7 for the desired checkerboard data pattern. After the predetermined byte-program time of around 1 ms, the Vt of each programmed cell FT0, FT2, FT4 and FT6 in the selected first byte is programmed to the desired value of −2.0V. The remaining cells of FT1, FT3, FT5 and FT7 in the selected first byte and the eight cells of FT0-FT7 in the remaining 127 bytes in SWL0 are not programmed and the data remain unchanged after the byte-program operation.

One concern in the conventional 2T FLOTOX-based EEPROM array is the so-called channel punch-through. In the example described above, channel punch-through may occur in FT0, FT2, FT4 and FT6 devices of the first selected byte. This is due to the HV of 16.0V simultaneously applied across over the four channel regions of FT0, FT2, FT4 and FT6, and the common source line SL0. Once the punch-through happens, four severe leakages would flow from the four selected channels to SL0. As a result, 16.0V cannot be sustained within the channel regions of the four FTa devices in FT0, FT2, FT4 and FT6, and the desired program operation would fail. This may happen as long as at least one of BL0-BL7 is coupled to 16.0V. Therefore, the channel lengths of all FTb devices have to be kept larger to avoid the punch-through effect, and thus the cell size of the EEPROM array is large and difficult to scale below 0.13 um technology.

FIG. 1E is a table showing the biased voltage conditions for three key byte-alterable operations of a selected byte of the conventional FLOTOX-based EEPROM cell array 100 shown in FIG. 1C. These three key byte-alterable operations include byte-read, byte-erasure and byte-program. A set of the preferred biased voltages for the selected and unselected BL0-BL7, SL, FGBL, SWLn and FWLn is shown, where SWLn and FWLn represent the corresponding SWL and FWL of the selected word line n.

In a typical byte-read operation of the EEPROM array 100 shown in FIG. 1D, a byte is selected. For example, eight bit lines BL0-BL7, one SL, one FGBL, one SWL and one FWL are selected. In this case, the single selected SL is coupled to ground via a source line decoder, while the eight selected bit lines BL0-BL7 are coupled to a voltage value of around 1.0V and connected to eight sense amplifiers through a bit line decoder. Each sense amplifier reads one bit of the cell current to determine if the stored binary data is “1” or “0” from the Vt of the corresponding cell.

Because the Vt of the cell is either VtL=−2.0V in a conduction state or VtH=+2.0V in a non-conduction state, the gate of the read cell, which is connected to the selected FWL, is coupled to Vread through the FWLT transistor whose drain node is connected to FGBL which is set to Vread. The preferred value of Vread is set to between VtL and VtH for a correct reading. Vread is preferably set in the range between 0V to 1V. The reason that Vread voltage can be passed to FTWL from FGBL is that the gate voltage of FWLT is coupled to a power supply voltage VDD of SWL during the read operation. In most EEPROM applications, VDD is above +1.5V which turns on FWLT to fully pass FGBL voltage which is less than 1.0V.

In a typical byte-erasure operation of the EEPROM array 100, a byte is also selected. In other words, eight bit lines BL0-BL7, one SL, one FGBL, one SWL and one FWL are selected. In this case, the single selected SL is coupled to ground via a source line decoder and the eight selected bit lines BL0-BL7 are also coupled to 0V via a bit line decoder. Both the selected FGBL and SWL are coupled to a HV in the range from +15.0V to +17.0V, depending on the EEPROM process and EEPROM cell erasure characteristics.

With reference to FIG. 1D, a voltage of 16V on the selected SWL can turn on the selected FWLT NMOS device to pass the required gate voltage of 16.0V on FGBL to the selected FWL which is connected to the Poly2 gates of a selected byte of the 2T EEPROM cell array. With the Poly2 gates of the selected FT transistors coupled to 16V and the channel regions of the selected FTa transistors at 0V, a FN tunneling effect is induced on the selected eight FT cells collectively and simultaneously. As a result, the Vt of each FT cell of a selected byte is increased to a desired value of +2.0V after a predetermined time of an erasure pulse of about 1 ms. All the FWL voltages of unselected cells in the remaining unselected bytes in the selected page or in other unselected pages of the EEPROM array are grounded so that no FN tunneling effect may occur and the data of unselected cells can remain unchanged.

In a typical byte-program operation of the 2T EEPROM array 100, a byte is selected as seen in FIG. 1D. The selected SWL is coupled to a HV in the range from +15.0V to +17.0V depending on the EEPROM process and the EEPROM cell program characteristics, and the selected FGBL is biased at 0V. One word line SWL is selected at a time. The selected bit lines in BL0-BL7 are coupled to a same HV of 16.0V, while the unselected bit lines of unselected cells in a selected byte are coupled to ground, depending on the desired programmed pattern.

With reference to FIG. 1D, a voltage of 16V on the selected word line SWL can turn on the selected ST NMOS device to pass the required voltage of 16.0V from the selected bit lines to the channel region of the selected FTa transistor with FWL biased at 0V. With the Poly2 gate of the selected FT biased at 0V of FWL and the channel region of selected FTa at 16.0V, a reverse FN tunneling effect of the byte-program is induced on the tunnel layer between the floating-gate and the channel region of each selected FTa of the selected FT cells collectively and simultaneously. The stored electrons in the floating-gates of the selected FT cells are expelled out to the channel regions of the cells. Thus, the Vt of each selected FT cell of a selected byte is decreased to a desired value of −2.0V after a predetermined time of a programmed pulse of about 1 ms.

The binary data of the EEPROM cell array are changed from “1” to “0” for those selected cells in the selected byte after the byte-program operation. For those unselected cells, the stored electrons are not affected and thus the stored data remain unchanged after the program operation. All the SWL and BL voltages of unselected cells in the remaining unselected bytes in the selected page or in other unselected pages of the EEPROM array are grounded so that no reverse FN tunneling effect may occur and the data of the unselected cells can remain unchanged.

As explained above, a required 16.0V has to be applied from BL to the channel of FTa of the selected programmed cell. The 16.0V HV is supplied from an on-chip charge-pump circuit and is coupled through the selected BLs with the selected SWL biased at same 16V. Because the HV is supplied from a weak source, any leakage along the selected path would result in the voltage drop across the tunnel-oxide of the selected cells, thus the FN byte-program would fail. There are several leakage factors such as ST and FT N-plus junction breakdown to P-substrate of a cell, the leakage between adjacent BLs, and the channel punch-through that may occur in the FTb device. The punch-through effect is most severe when the cell size is scaled down. Another BL leakage path may also occur through those unselected cells in the same selected 16V BL. This leakage is due to the occurrence of the channel punch-through of unselected ST devices connected to each BL.

The 2T FLOTOX-based EEPROM non-volatile-memory described above has been extensively used in the byte-alterable data storage market place for more than two decades since its first introduction in 1980. The byte-alterable function is the most popular feature for meeting the stringent endurance requirement of one million endurance cycles due to an extremely high data changing rate in many practical applications. As discussed above, the completion of a successful byte-write operation means that the EEPROM cells in a selected byte have gone through both successful FN erasure and FN program operations, regardless whether the initial Vt of the cell is VtH (“1”) or VtL (“0”). With the completion of the byte-erasure operation in about 1 ms, the data of all eight bits in the selected byte become “1”. After the byte-program operation of about 1 ms, the selected bits would then be programmed to “0”. Both byte-erasure and byte-program operations use the low-current FN channel tunneling scheme and are performed in unit of byte, which is why the EEPROM is referred to as a byte-alterable EEPROM.

In a practical embedded EEPROM application, a page-alterable function combined with a byte-alterable function has been extensively used to meet the same specification of 1M endurance cycles. In wafer-sort production environment, more design functions of chip-erasure and chip-program can be incorporated to reduce the lengthy testing time for die cost reduction. The most important erasure and program size of 2T FLOTOX-based EEPROM is performed in the unit of a single byte on chips with only a low voltage (LV) VDD supply in today's broad EEPROM memory applications.

As explained above, the conventional EEPROM byte-write operation involves two steps of HV (16.0V) stress over the thin tunnel-oxide gate layer of the EEPROM cells in the sequence of the first erasure and the second program cycles. For example, if the eight (8) cells of the selected byte have the same initial VtL and only four (4) bits are selected to be programmed to VtH, all eight cells have to be erased collectively to VtH first and then the four unselected bits (cells) are programmed back to VtL. In other words, four unselected cells have gone through the unnecessary or undesired FN HV stress to have electrons injected into and expelled out of the floating gate. As a result, the program/erasure (P/E) endurance of the EEPROM is degraded, the product P/E endurance cycles are reduced and the product life cycle is shortened.

The drawback of unnecessary HV (16V) over stress on the thin tunnel-oxide gate of EEPROM cells is partly due to the unique byte-alterable array architecture with a shared horizontal source line of the selected byte in the conventional FLOTOX-based 2T EEPROM array. The byte-alterable array architecture of a 2T EEPROM array has potential bit line program leakage paths from the 16V bit lines of the selected cells to the 0V of adjacent bit lines of the unselected cells sharing a common source line as pointed out above. This punch-through leakage flows from the 16V bit lines through the ST, FTa and FTb devices of the selected cells to the selected common source line. With the source line being biased at 0V, the required voltage of 16V on the drain node of the FTa device cannot be sustained. As a result, the EEPROM program operation would fail. The unsuccessful program operation in the byte-alterable FLOTOX-based EEPROM array can easily happen when the channel lengths of FTb and ST are reduced.

In summary, the channel lengths of all ST and FTb transistors of conventional EEPROM cells have to be kept large enough to prevent any punch-through leakage because a 16.0V BL HV across the channel region of a cell is always required in the conventional EEPROM cell array architecture. As a consequence, the scalability of the cell size has encountered a big bottleneck in the traditional EEPROM design. An approach to solving this scalability issue is urgently needed for high-density EEPROM designs. In addition, for a high-density embedded code storage application, a similar scalability issue has to be solved in order to meet the strong demand for a smaller flash cell size in a same chip with EEPROM in the embedded micro-controller unit (MCU) market place.

### SUMMARY OF THE INVENTION

The present invention discloses a novel array circuit architecture for 1T FLOTOX-based flash and 2T FLOTOX-based EEPROM arrays along with a respective set of preferred biased voltage conditions for BL, SL, FGBL, SWL and FWL to greatly reduce the punch-through leakage flowing through the unselected EEPROM or flash cells. In addition, the present invention provides both 1T FLOTOX-based flash and 2T FLOTOX-based EEPROM arrays with a bit-alterable write function. With the added bit-alterable write function, the elimination of unnecessary 16.0V HV stress on the thin tunneling oxide gate layer of the memory cells can be achieved for a superior endurance cycles and thus a longer product life.

Accordingly, an object of the present invention is to provide a 2T FLOTOX-based EEPROM array architecture in which a plurality of 2T FLOTOX-based EEPROM cells are organized in a plurality of rows and columns for a typical application that requires byte-alterable data storage. Unlike the traditional EEPROM array, the present 2T FLOTOX-based EEPROM array architecture has no common horizontal source line that is connected to a plurality of memory cells in a same word line.

Another object of the present invention is to provide a novel 2T FLOTOX-based EEPROM array in which the number of source lines is made identical to the number of bit lines. Each bit line is connected to the drains of all the associated ST transistors organized in a vertical column of the novel 2T FLOTOX-based EEPROM array in the present invention and the corresponding source line is connected to the common sources of all the associated FT transistors in the vertical column. Both bit lines and source lines are preferably made in parallel and laid out vertically in silicon as a plurality of metal lines perpendicular to the plurality of horizontal word lines.

Another object of the present invention to provide a preferred erasure method for a novel 2T FLOTOX-based EEPROM array. Unlike the traditional byte-erasure method, the present invention allows the Vt to increase only on the selected 2T FLOTOX-based EEPROM cells by using novel FN bit-erasure biased conditions in accordance with a preferred operation.

It is another object of the present invention to provide a preferred program method of the novel 2T FLOTOX-based EEPROM array. Unlike the traditional byte-program method, the present invention allows the Vt to decrease only on the selected 2T FLOTOX-based EEPROM cells by using novel reverse FN bit-program biased conditions in accordance with a preferable operation.

A further object of the present invention is to provide a set of preferred biased program conditions for BLs and SLs of the novel 2T FLOTOX-based EEPROM array to reduce the HV drop across the channel region between the drain node and source node of the double-poly FTb transistor of each FT in the novel 2T FLOTOX-based EEPROM array of the present invention.

It is yet a further object of the present invention to provide a set of preferred biased program and erasure conditions for BLs, SLs, FGBL and SWLn of the novel 2T FLOTOX-based EEPROM array to allow the same byte-write operation similar to the conventional byte-alterable 2T FLOTOX-based EEPROM array.

In accordance with the present invention, another object is to provide a 1T FLOTOX-based flash cell structure which is preferably formed by removing the HV select transistor (ST) from a conventional FLOTOX-based 2T EEPROM cell for cell size reduction. Similar to the 2T EEPROM cell, the 1T flash cell of the present invention employs the low-current FN tunneling scheme to perform both block-erasure and page-program operations as well as an identical manufacturing process on the same chip.

Another object of the present invention is to provide a novel 1T FLOTOX-based flash array architecture in which a plurality of 1T FLOTOX-based flash cells are organized in a plurality of rows and columns for a typical application that requires block-alterable code storage. The 1T FLOTOX-based flash cell is made of a double-poly floating-gate transistor (FT) only without a select transistor to reduce the cell size. Unlike the traditional EEPROM or flash array, the present 1T FLOTOX-based flash array architecture has no common horizontal source line that is connected to a plurality of memory cells in a same word line.

Another object of the present invention is to provide a novel 1T FLOTOX-based flash array in which the number of source lines is made identical to the number of bit lines. Each bit line is connected to the drains of all the associated FT transistors organized in a vertical column of the novel 1T FLOTOX-based flash array in the present invention and the corresponding source line is connected to the common sources of all the FT transistors in the vertical column. Both bit lines and source lines are preferably made in parallel and laid out vertically in silicon as a plurality of metal lines perpendicular to all horizontal word lines to reduce area for superior cell scalability.

Another object of the present invention to provide a preferred erasure method for a novel 1T FLOTOX-based flash array. Unlike the traditional byte-erasure method, the present invention allows the Vt to increase only on the selected 1T FLOTOX-based flash cells by using novel FN bit-erasure biased conditions in accordance with a preferred operation.

It is another object of the present invention to provide a preferred program method of the novel 1T FLOTOX-based flash array. Unlike the traditional byte-program method, the present invention allows the Vt to decrease only on the selected 1T FLOTOX-based flash cells by using novel reverse FN bit-program biased conditions in accordance with a preferred operation.

A further object of the present invention is to provide a set of preferred biased program conditions for BLs and SLs of the novel 1T FLOTOX-based flash array to reduce the HV drop across the channel region between the drain node and source node of the double-poly FTb transistor of each FT in the novel 1T FLOTOX-based flash array of the present invention.

It is yet a further object of the present invention to provide a set of preferred biased program and erasure conditions for BLs, SLs and SWLs of the novel 1T FLOTOX-based flash array to allow the same block-write operation similar to the conventional block-alterable flash array.

According to the present invention, another object is to provide a combo NMV array which comprises both 1T FLOTOX-based flash array and 2T FLOTOX-based EEPROM array based on the same FLOTOX-based cell structure, cell FN tunneling schemes, and the same manufacturing process. The 1T FLOTOX-based flash array is preferable to have write options of bit-alterable, page-alterable and block-alterable functions. Similarly, the 2T EEPROM array is preferable to have similar options of bit-alterable, byte-alterable and page-alterable functions.

Another object of the present invention is to provide a combo NMV array, which comprises 1T FLOTOX-based flash array and 2T FLOTOX-based EEPROM array based on the same FLOTOX-based cell structure, cell FN tunneling schemes, and same manufacturing process. The two arrays may share the same address buffers, word line decoder, bit line decoder, source line decoder, page buffers and sense amplifiers and output buffers as well as chip enable (CE) and output enable (OE) control signals and the same clock input.

### BRIEF DESCRIPTION OF THE DRAWINGS

FIG. 1A shows a circuit diagram of a conventional 2T FLOTOX-based EEPROM cell.

FIG. 1B shows the circuit diagram of a virtual 3T cell equivalent to the 2T FLOTOX-based EEPROM cell of FIG. 1A.

FIG. 1C shows a cross-sectional view of the device structure for the 2T EEPROM cell of FIG. 1A.

FIG. 1D shows an exemplary circuit of two bytes of a conventional 2T FLOTOX-based 2T EEPROM cell array.

FIG. 1E is a table showing the biased voltage conditions for three key operations of a selected byte of the conventional 2T FLOTOX-based EEPROM cell array of FIG. 1D.

FIG. 2A shows a circuit diagram of a 2T FLOTOX-based EEPROM cell, which is identical to the circuit of a conventional 2T FLOTOX-based EEPROM cell shown in FIG. 1, of the present invention.

FIG. 2B shows the circuit diagram of a virtual 3T cell equivalent to the 2T FLOTOX-based EEPROM cell of FIG. 2A according to the present invention.

FIG. 2C shows an exemplary circuit of two bytes of a 2T FLOTOX-based EEPROM cell array of the present invention.

FIG. 2D is a table showing the preferred biased voltage conditions for three key byte-alterable operations of a selected byte of a 2T FLOTOX-based EEPROM cell array shown in FIG. 2C according to the byte-alterable operations of the present invention.

FIG. 2E is a table showing the preferred biased voltage conditions for three key bit-alterable operations of a selected byte of a 2T FLOTOX-based EEPROM cell array shown in FIG. 2C according to the bit-alterable operations of the present invention.

FIG. 3A shows a circuit diagram of a 1T FLOTOX-based flash cell according to the present invention.

FIG. 3B shows that a true equivalent circuit of the 1T FLOTOX-based flash cell of FIG. 3A according to the present invention is a virtual 2T flash cell.

FIG. 3C shows the cross-sectional view of the device structure of the 1T FLOTOX-based flash cell of FIG. 3A.

FIG. 3D shows an exemplary circuit of two bytes of a 1T FLOTOX-based flash cell array of the present invention for page-alterable and block-alterable code storage applications.

FIG. 3E is a table showing the preferred biased voltage conditions for three key operations of a selected byte of the 1T FLOTOX-based flash cell array shown in FIG. 3D according to the byte-alterable operations of the present invention.

FIG. 3F is a table showing the preferred biased voltage conditions for three key operations of a selected byte of the 1T FLOTOX-based flash cell array shown in FIG. 3D according to the bit-alterable operation of the present invention.

FIG. 4 is a circuit block diagram of a FLOTOX-based EEPROM and flash combo array manufactured on a same chip according to the present invention.

### DETAILED DESCRIPTION OF THE INVENTION

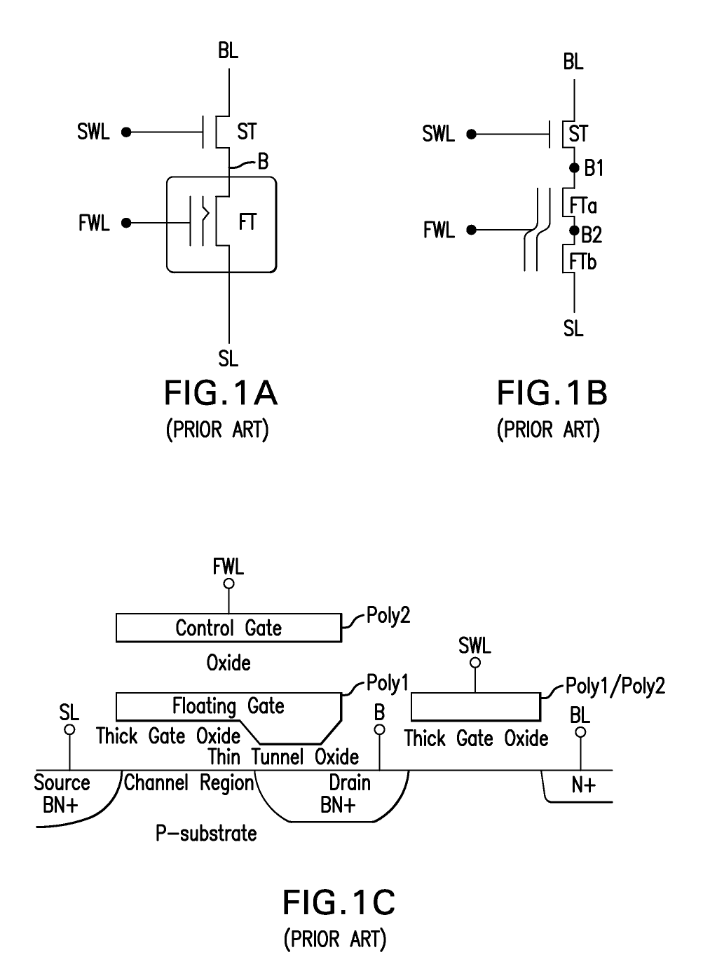

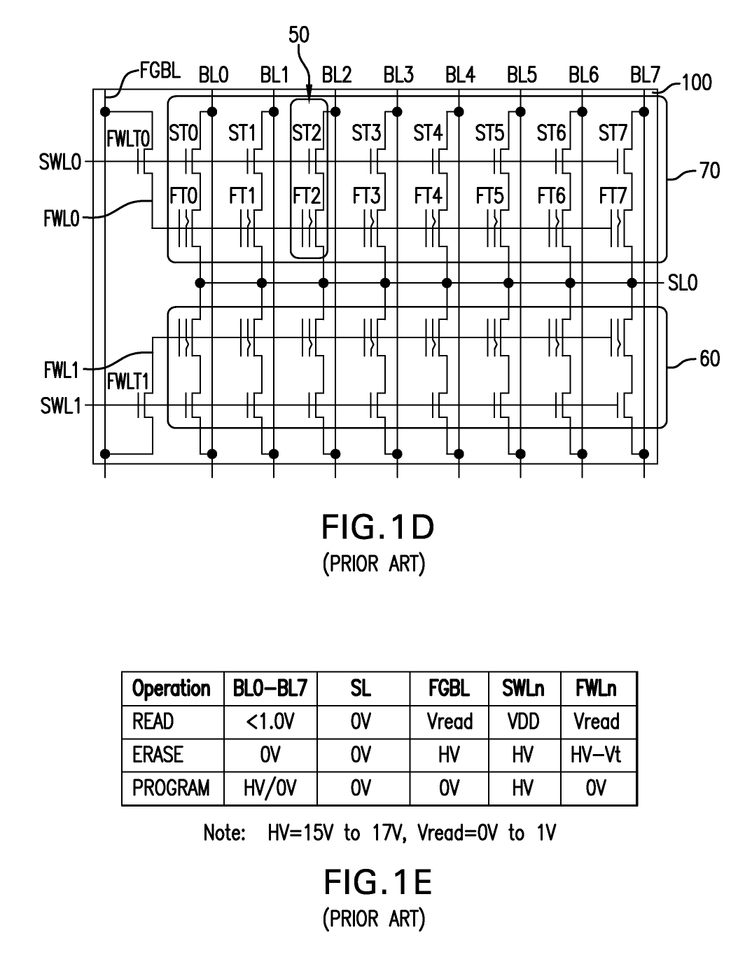

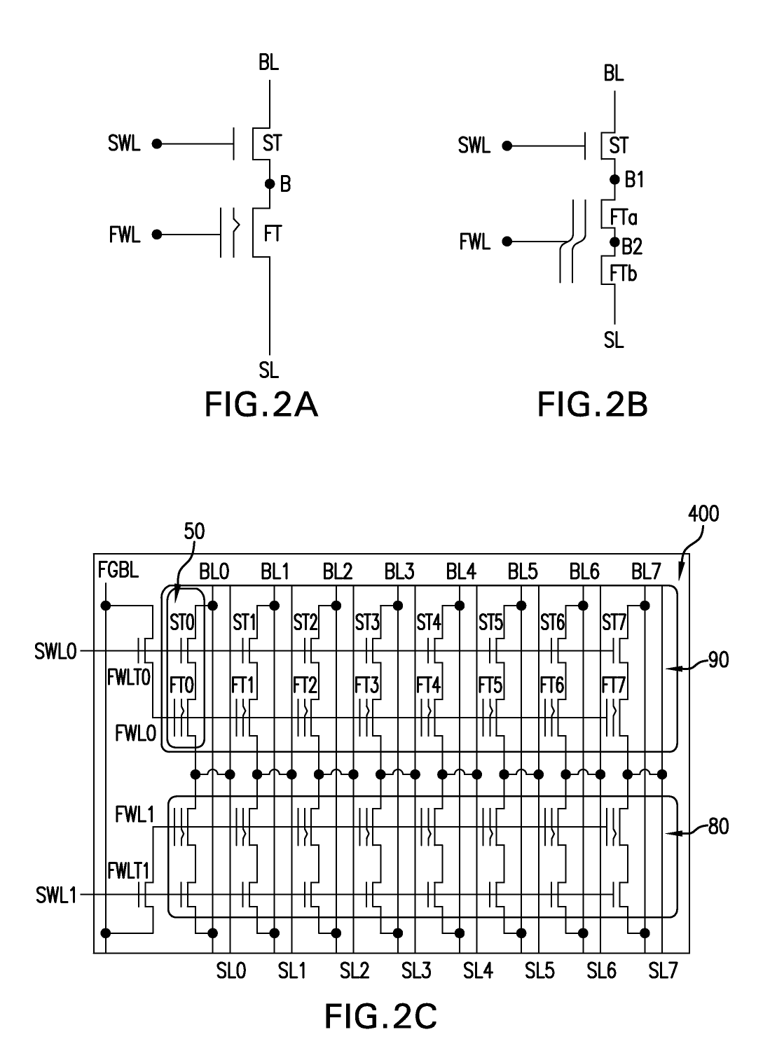

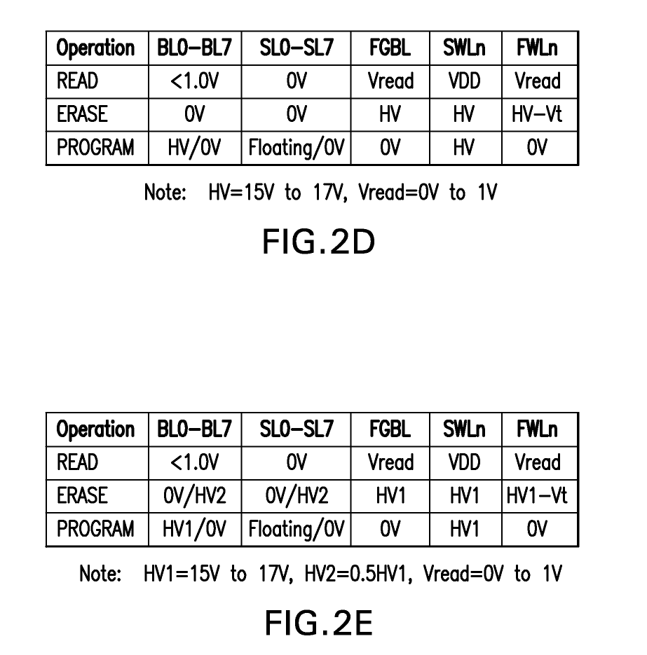

With reference to FIGS. 2A-2C, the present invention provides a novel 2T FLOTOX-based EEPROM cell array which is both byte-alterable and bit-alterable. As shown in FIGS. 2A and 2B, the basic 2T FLOTOX-based EEPROM cell structure in the EEPROM cell array shown in FIG. 2C is identical to the conventional 2T FLOTOX-based EEPROM cell structure shown in FIGS. 1A and 1B. The detailed description for the EEPROM cell structure and its operation principle has been given in Background of the Invention, and therefore will not be repeated here. As mentioned in the description for FIG. 1A, SL is always connected to VSS in the traditional EEPROM array. However, SL shown in FIG. 2A is connected to a preferred read, program or erasure voltage respectively through a source line decoder in accordance with the present invention.

FIG. 2C shows an exemplary circuit of a 2T FLOTOX-based EEPROM cell array 400 according to the present invention for byte-alterable and bit-alterable code storage. For simplicity, only the circuit of two bytes 80, 90 in the 2T FLOTOX-based EEPROM cell array is shown. Each byte of the EEPROM cell array includes eight select transistors and eight floating-gate transistors. In byte 90, they are denoted as ST0-ST7 and FT0-FT7 respectively. Byte 90 also comprises eight separate vertical bit lines, denoted as BL0-BL7, connected to the eight corresponding drains of the eight ST transistors, and eight separate source lines, denoted as SL0-SL7, connected to the eight corresponding source nodes of the EEPROM cells. In contrast to the conventional 2T FLOTOX-based EEPROM cell array, the present invention has no common horizontal source line connected to and shared by the source nodes of the EEPROM cells in byte 90.

As shown in FIG. 2C, each vertical bit line BLn has its corresponding dedicated vertical source line SLn and both BLn and SLn are preferably running in parallel in a direction perpendicular to the common horizontal word lines in the EEPROM cell array of the present invention. The gates of ST0-ST7 of each byte of a plurality of bytes in the same row and the gate of a HV single-poly NMOS transistor, denoted as FWLT0, are connected together to a common horizontal word line, denoted as SWL0. The drain of FWLT0 is connected to a gated byte line FGBL. The source node of FWLT0 and the eight corresponding Poly2 gates of FT0-FT7 are connected to a common Poly2 gate line FWL0. The channel lengths of ST and FTb of the 2T FLOTOX-based EEPROM cell of the present invention are preferably made smaller than the traditional one for cell size reduction because there is less leakage concern during the FN channel-program operation.

FIG. 2D is a table showing the preferred biased voltage conditions for three key byte-alterable operations of a selected byte of a 2T FLOTOX-based EEPROM cell array 400 shown in FIG. 2C according to the byte-alterable operations of the present invention. The three key byte-alterable operations include byte-read, byte-erasure and byte-program. A set of preferred biased voltages for the selected and unselected BLs of BL0-BL7 and SLs of SL0-SL7, FGBL, SWLn and FWLn is shown, where SWLn and FWLn represent the corresponding SWL and FWL of the selected word line n.

In a typical byte-read operation of the EEPROM cell array 400, a byte is selected. For example, BL0-BL7, SL0-SL7, SWL0 and FWL0 are selected if the first byte of the first word line in the EEPROM cell array is to be read. In this case, the eight selected source lines SL0-SL7 are coupled to ground via a source line decoder, while the eight selected bit lines BL0-BL7 are coupled to a voltage value of around 1.0V and connected to eight sense amplifiers through a bit line decoder. Each sense amplifier reads one bit of the cell current to determine if the stored binary data is “1” or “0” from the Vt of the corresponding cell. Similar to the conventional EEPROM cell, the Vt of the EEPROM cell of the present invention is either VtL=−2.0V in a conduction state or VtH=+2.0V in a non-conduction state. The gate voltage Vread of a read cell is connected to FWL0 which is coupled to Vread through the FWLT0 transistor with its drain node coupled to FGBL. The preferred value of Vread is set between VtL and VtH for a correct reading. Vread is preferably set in the range of 0V to 1V as explained previously.

In a typical byte-erasure operation of the EEPROM array 400, a byte is selected. In other words, eight bit lines BL0-BL7 and eight corresponding source lines SL0-SL7, one FGBL, one SWL and one FWL are selected. In this case, the eight selected source lines SL0-SL7 are coupled to ground via a source line decoder and the eight selected bit lines BL0-BL7 are coupled to 0V via a bit line decoder. Both the selected FGBL and SWL are coupled to a HV in the range from +15.0V to +17.0V, depending on the EEPROM process and EEPROM cell erasure characteristics.

With reference to FIG. 2C, a voltage of around 16V on the selected SWL can turn on the selected FWLT NMOS device to pass the required gate voltage of approximately 16.0V on FGBL to the selected FWL, which is connected to the Poly2 gates of a selected byte of the 2T EEPROM cells array. With the gate of the selected FTa biased at about 16.0V and the channel region of the selected FTa at 0V, a FN tunneling effect would be induced on the selected eight FT cells collectively and simultaneously. As a result, the Vt of each FT cell of a selected byte is increased to a desired value of +2.0V after a predetermined time of an erasure pulse of about 1 ms. This step is automatically performed by an on-chip state machine. Usually the longer erasure pulse of 1 ms is used to achieve a high successful rate so that an erase-verify step can be skipped to simplify the logic design of the state machine. All the FWL voltages of unselected cells in the remaining unselected bytes in the selected page or in other unselected pages of the EEPROM array are grounded so that no FN tunneling may occur and the data of unselected cells can remain unchanged.

In a typical byte-program operation of the 2T EEPROM array 400, a byte is selected as shown in FIG. 2C. The selected SWL is coupled to a HV in the range from +15.0V to +17.0V depending on the EEPROM process and the EEPROM cell program characteristics, and the selected FGBL is biased at 0V. One SWL is selected. The selected bit lines of BL0-BL7 are coupled to a same HV in the range between 15.0V to +17.0V and the selected source lines of SL0-SL7 are left as floating or set at a voltage approximately one half of the HV. The unselected bit lines and source lines of unselected cells in a selected byte are coupled to ground, depending on the desired programmed pattern.

With reference to FIG. 2C, a voltage of around 16V on the selected word line SWL can turn on the selected ST NMOS device to pass the required voltage of 16.0V from the selected bit lines to the channel region of the selected FTa transistor with FWL biased at 0V because FWLT0 is also turned on and FGBL is connected to 0V. With the Poly2 gate of the selected FT cell biased at 0V of FWL and the channel region of the selected FTa at about 16.0V, a reverse FN tunneling effect of byte-program is induced on the tunnel layer between the floating-gate of the selected FTa and the channel region on each of the selected FT cells collectively and simultaneously. The stored electrons in the floating-gates of the selected FT cells are expelled out to the channel regions of the cells. Thus, the Vt of each selected FT cell of a selected byte is decreased to a desired value of −2.0V after a predetermined time of a programmed pulse of about 1 ms.

The binary data of the EEPROM would be changed from “1” to “0” for those selected cells in the selected byte after the byte-program operation. For those unselected cells, the stored electrons are not affected and thus the stored data remain unchanged after the program operation. This second step of byte-program in a byte-write operation is also automatically performed by an on-chip state machine following the successful first step of byte-erasure. Usually a longer program pulse of 1 ms is used to achieve a high successful rate so that a program-verify step can be skipped to simplify the logic design of the state machine. All the SWL and BL voltages of unselected cells in the remaining unselected bytes in the selected page or in other unselected pages of the EEPROM array are grounded so that no FN tunneling effect may occur and the data of the unselected cells can remain unchanged.

The 2T EEPROM array of the present invention as shown in FIG. 2C provides a significant advantage over the conventional 2T EEPROM array as shown in FIG. 1D. As explained above, a required 16.0V has to be applied from BL to the channel of FTa of the selected programmed cells. The 16.0V HV is supplied from an on-chip charge-pump circuit and is coupled through the selected BL with the selected SWL biased at same 16V. Because the HV is supplied from a weak source, any leakage along the selected path would result in the voltage drop across the tunnel-oxide of selected cells, thus the FN byte-program would fail. Punch-through is the most severe issue when both ST and FTb are scaled down in the conventional 2T EEPROM array.

In the 2T EEPROM array of the present invention, the punch-through leakage would not flow from the 16.0V channels of FTb transistors of the selected cells to the common 0V source line. Instead, because each corresponding SLn is set to be floating, the flow of a leakage current is suppressed. Even if there is any leakage, the leakage charge is at most re-distributed between one selected pair of BLn and SLn. In general, if the cell length is not in an extreme case and 16V BLn only leaks 5V to the SLn and stops, the normal BLn voltage of 16V can still be kept in the channel of FTa of the selected EEPROM cell. As a result, the byte-program operation can still be performed successfully on the selected cells even with partial punch-through phenomenon.

Therefore, the channel lengths of all ST and FTb transistors of the 2T FLOTOX-based EEPROM cells in the present invention can be properly reduced without worrying about any punch-through leakage. As a result, the size of the EEPROM cell can be further reduced by using the novel EEPROM array of the present invention.

FIG. 2E is a table showing the preferred biased voltage conditions for three key bit-alterable operations of a selected byte of a 2T FLOTOX-based EEPROM cell array 400 shown in FIG. 2C according to the bit-alterable operations of the present invention. The three key bit-alterable operations include byte-read, bit-erase and bit-program. A set of preferred biased voltage conditions for the selected and unselected bit lines of BL0-BL7, source lines of SL0-SL7, FGBL, SWLn and FWLn is shown. The typical byte-read operation of the 2T EEPROM array in the bit-alterable operation is identical to that in the byte-alterable operation. Therefore, the byte-read operation is not described again.

In a typical bit-erasure operation of the 2T EEPROM array 400 of the present invention, a flexible number of bits are selected for a write operation. The selected SWL is coupled to HV1 in the range between 15.0V to 17.0V along with the selected FGBL biased at same HV1 so that the selected FWL would be coupled to a voltage near 16V. In addition, a few or all of BL0-BL7 and a few or all of SL0-SL7 of the selected FTa cells, depending on the desired data in the selected byte, are coupled 0V to induce FN tunneling effect while the non-selected BLs are coupled to HV2. HV2 is typically set at one half of HV1 and is approximately at +8.0V for inhibiting a FN-eraseure operation in order to prevent the FN tunneling from occurring within the predetermined bit-erasure time of 1 ms. After the bit-erasure operation, the Vt of each selected FT cell is erased to a VtH value and the Vt of each unselected FT cell stays unchanged in accordance with the present invention. The remaining BLn and SLn in the unselected 127 bytes in the selected SWL are all coupled to ground. Unselected FGBL is coupled to ground as well.

With reference to FIG. 2C, a voltage of around 16V on the selected SWL can turn on the selected FWLT single-poly NMOS device to pass the required gate voltage of 16.0V on FGBL to only one selected FWL which is connected to all the Poly2 gates of a selected byte of the 2T EEPROM cells of the present invention. With the gate of a selected FTa connected to the FWLT biased at 16.0V and the channel region of the selected FTa at 0V, the floating gate of FTa across the tunneling oxide layer would induce the FN tunneling effect.

According to the present invention, the gate of an unselected FTa of the selected SWL is biased at HV1 along with the channel region of the unselected FTa at HV2, the coupling voltage on the floating-gate of the unselected FTa across the tunneling oxide layer would not be high enough to induce the FN tunneling effect. As a result, only the Vt of each selected FT cell would be increased to a desired erasure value of +2.0V and the Vt of each unselected bit remains unchanged after a predetermined time of an erasure pulse of about 1 ms. This bit-erasure step is automatically performed by an on-chip state machine. Usually the longer erasure pulse of 1 ms is used to achieve a high successful rate so that an erase-verify step can be skipped to simplify the logic design of a state machine. All the FWL voltages of unselected cells in the remaining unselected bytes in the selected page or in other unselected pages of the EEPROM array are grounded so that no FN tunneling effect can occur and the data of unselected cells can remain unchanged.

In a typical bit-program operation of 2T EEPROM array 400 shown in FIG. 2C of the present invention, any flexible number of bits out of a selected byte can be performed for data change. A selected SWL is coupled to a HV1 and the selected FGBL is connected to a 0V for a bit-program. The number of the selected cells for bit-program is flexible from 1 to 8 and the bit lines of the selected cells in the selected byte are coupled to a same HV1 in the range between 15.0V to 17.0V. The source lines of the selected cells are set floating or coupled to a value of HV2. The bit lines and source lines of the unselected cells in the selected byte are coupled to ground. The floating voltage or the HV2 biased voltage for the selected cell is used to prevent the fatal punch-through problem from occurring in the channel region of the FTb.

With reference to FIG. 2C, a voltage of 16V on the selected word line SWL can turn on the selected ST NMOS device to pass the required voltage of 16.0V from the selected bit lines to the channel region of the selected FTa transistor with FWL biased at 0V because FWLT0 is also turned on and FGBL is connected to 0V to induce a reverse FN tunneling effect. With the Poly2 gate of the selected FT cell biased at 0V of FWL and the channel region of selected FTa at 16.0V, a reverse FN tunneling effect of bit-program is induced between the floating-gate of the selected FTa and the channel region on each of the selected FT cells. The stored electrons in the floating-gate of the selected FT cell are expelled out to the channel region of the cell. Therefore, the Vt of any selected bit in a selected byte can be programmed to the desired value of −2.0V after a predetermined time about 1 ms.

The binary data of the EEPROM would be changed from “1” to “0” after the bit-program operation for those selected cells. For those unselected cells, the stored electrons are not affected and thus the stored data remain unchanged after the bit-program operation. Similarly, this second-step of bit-program in a bit-write operation is also automatically performed by an on-chip state machine following the successful first step of bit-erasure. Usually a longer program pulse of 1 ms is used to achieve a high successful rate so that a program-verify step can be skipped to simplify the logic design of the state machine. All the voltages of SWL, BLs, SLs and FGBL of unselected cells in the remaining unselected bytes in the selected page or in other unselected pages of the EEPROM array of the present invention are grounded so that no reverse FN tunneling effect may occur and the data of the unselected cells can remain unchanged.

With the EEPROM cell array shown in FIG. 2C and the preferred biased voltages set for the selected BLn and SLn of the present invention, the punch-through issue in a bit-program operation can be solved or relaxed. As shown in FIG. 2E, in the bit-alterable program operation of the present invention, only a maximum of about 8V drop is coupled across the channel of the selected FTb rather than 16V, and thus the punch-through effect has been greatly reduced. In the case of a floating SL of the selected cell with a preferred shorter channel length of the FTb transistor, the 16.0V of BLn would leak to SLn up to about 8V and then be automatically stopped. In either case, the bit-program operation for the flexible number of the selected cells can still be performed successfully. The method of biasing SLn to floating has one advantage that it does not require an 8V HV2 source generator. Thus the charge-pump circuit design for HV can be further simplified and the cell size reduction can be economically achieved in this preferred bit-program operation of the present invention.

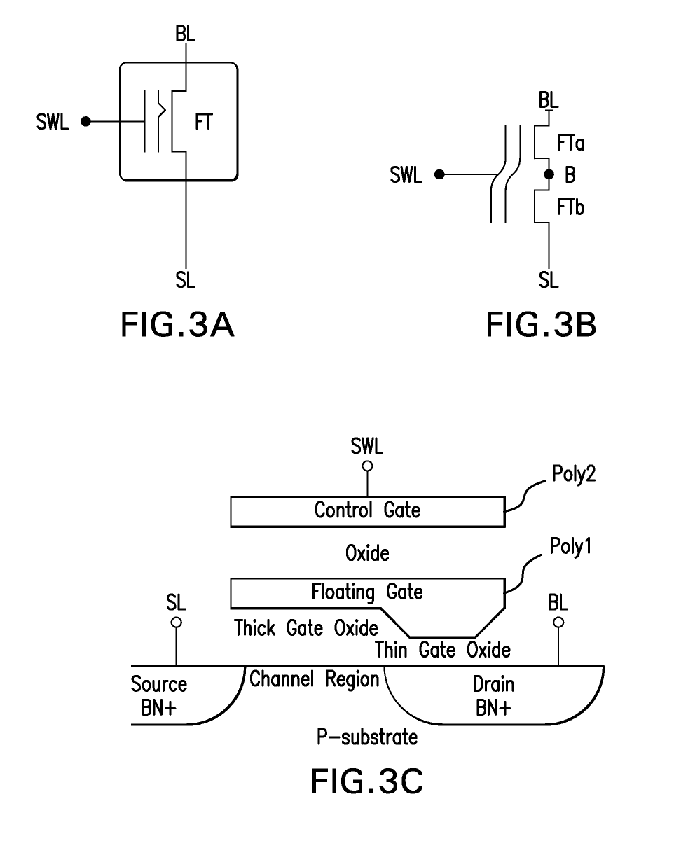

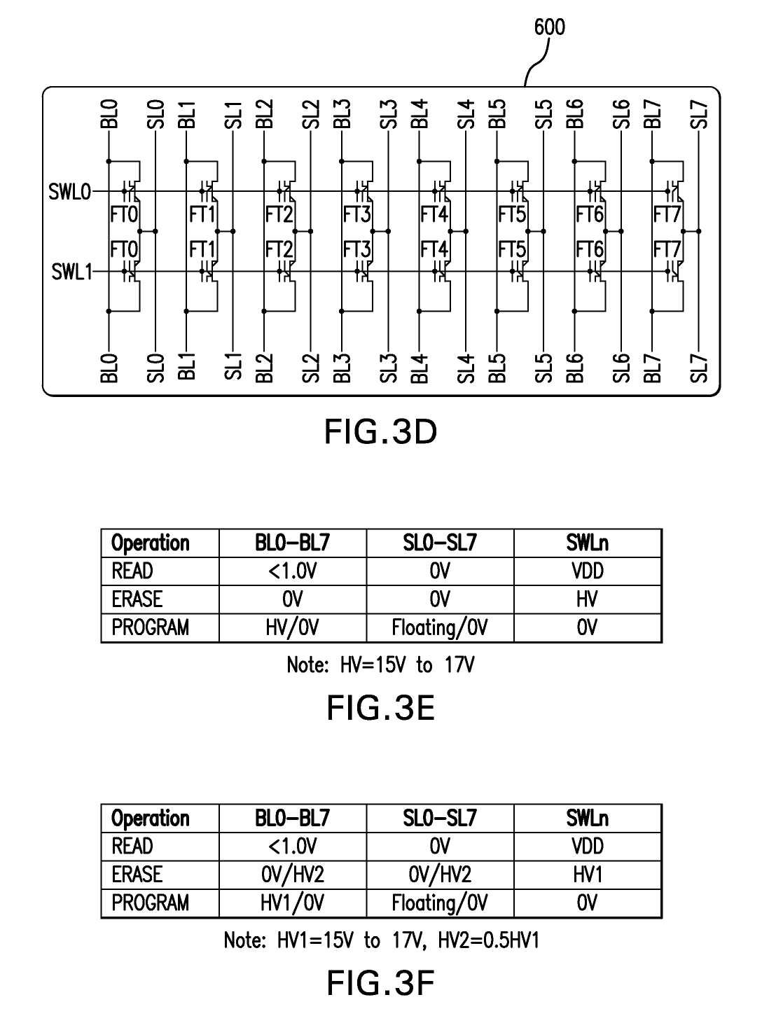

According to the present invention, the 2T FLOTOX-based EEPROM cell can be replaced by a 1T FLOTOX-based EEPROM flash cell for applications that require block-alterable code storage. FIG. 3A shows the circuit diagram of a 1T FLOTOX-based flash cell according to the present invention. In this flash cell, the select transistor (ST) is removed from the device structure of the conventional EEPROM cell and FIG. 3B show its corresponding virtual 2T flash cell. FIG. 3C shows the cross-sectional view of the device structure of the 1T FLOTOX-based flash cell of FIG. 3A. The reason why the 1T flash cell of FIG. 3A is equivalent to the virtual 2T flash cell of FIG. 3B is the same as why the 2T EEPROM cell of FIG. 1A is equivalent to the virtual 3T EEPROM cell of FIG. 1B. Therefore, the explanation can be referred to the previous description and is not repeated here for simplicity.

FIG. 3D shows an exemplary circuit of two bytes of a 1T FLOTOX-based flash cell array 600 of the present invention for page-alterable and block-alterable code storage applications. The flash array circuit comprises of two bytes including eight 1T FT cells of FIG. 3A. Each byte has eight vertical bit lines, BL0-BL7, connected to the corresponding drain node of FTa of each FT flash cell and another eight source lines, SL0-SL7, connected to the respective source node of FTb of each FT cell.

In a 2T FLOTOX-based EEPROM cell array 400 of FIG. 2C, the gates of FT cells of each byte in a word line has a dedicated FWLn for coupling to the common word line SWLn through the NMOS transistor FWLTn because of the byte-alterable requirement. The reason that an EEPROM cell array is much larger than a flash array is due to the requirement of the byte-alterable data function. In contrast, a flash array is used to store codes which are changed in unit of block in specification. In practice, a program memory size is larger than a single byte or a page. The block size is usually defined as 1 Mb that covers 1,000 word lines and 1,000 bit lines typically. During the block erase operation, the cells in the selected block of 1,000 WLs and 1,000 BLs are being erased collectively and simultaneously. Therefore, the gates of all FT cells associated with a word line in a flash array can be connected to a common word line without the need of any FWLTn device. As a result, the size of the flash array can be reduced.

Similar to the 2T FLOTOX-based EEPROM array of the present invention, the circuit of the 1T FLOTOX-based flash array of the present invention does not have a common horizontal source line generally seen in the circuit of the traditional 2T FLOTOX-based EEPROM array. Each vertical bit line BLn has its own dedicated source line SLn. The bit lines and source lines are preferably running in parallel in the direction perpendicular to the common horizontal word lines SWL in the flash array of the present invention. Because there is no byte-alterable need in data storage applications, the FWLT used in the traditional byte-alterable 2T FLOTOX-based EEPROM cell array has been removed. The channel length of the FTb of the flash cell of the present invention is preferably made shorter than that of the FTb in the traditional EEPROM cell for size reduction due to less leakage concern during the FN channel-program operation. The erasure and program operations for a code flash array are typically performed in unit of block with 100K P/E specification.

FIG. 3E is a table showing the preferred biased voltage conditions for three key operations of a selected page of the 1T FLOTOX-based flash cell array shown in FIG. 3D of the present invention. The three key byte-alterable operations include byte-read, byte-program and byte-erasure. A set of the preferred biased voltages for the selected and unselected BLs of BL0-BL7, SLs of SL0-SL7 and SWLn are shown. It should be noted that the same biased conditions can be used for a page-alterable and block-alterable 1T flash memory of the present invention. The definition of a page is a memory array of a plurality of bytes sharing the same SWL. The definition of a block is a memory array of a plurality of pages sharing the same BLs and SLs.

In a typical byte-read operation of the 1T flash array 600, a byte is selected. For example, BL0-BL7, SL0-SL7, and SWL0 are selected if the first byte of the first word line in the flash cell array is to be read. In this case, the eight selected source lines SL0-SL7 are coupled to ground via a source line decoder, while the eight selected bit lines BL0-BL7 are coupled to a voltage value of around 1.0V and connected to eight sense amplifiers through a bit line decoder. Each sense amplifier reads one bit of the cell current to determine if the stored binary data is “1” or “0” from the Vt of the corresponding cell. The Vt of the flash cell of the present invention is either VtL=1.0V in a conduction state or VtH=+4.0 to +5.0V in a non-conduction state.

In a typical byte-erasure operation of the flash cell 600, only one byte of BL and SL out of a page is selected along with one selected SWL. In this case, eight selected source lines SL0-SL7 of the selected byte are coupled to ground via a source line decoder and eight selected bit lines BL0-BL7 of the selected byte are also coupled to 0V via a bit line decoder. The selected SWLn is coupled to a HV in the range from +15.0V to +17.0V, depending on the flash cell erasure characteristics.

With reference to FIG. 3D, a voltage of around 16V on the selected SWL is connected to the Poly2 gates of the selected FTs in the word line. With the gate of the selected FTa biased at approximately 16.0V and the channel region of the selected FTa at 0V, a FN tunneling effect would be induced on the selected FT cells collectively and simultaneously. As a result, the Vt of each FT cell of a selected byte is increased to a desired value of +4.0V to +5.0V after a predetermined time of an erasure pulse of about 1 ms. This step is automatically performed by an on-chip state machine. Usually the longer erasure pulse of 1 ms is used to achieve a high successful rate so that an erase-verify step can be skipped to simplify the logic design of the state machine.

In a typical byte-program operation of the 1T flash array 600, the selected SWL is biased at 0V. The selected bit lines of BL0-BL7 are coupled to a same HV in the range between 15.0V to 17.0V, and the selected source lines of SL0-SL7 are left as floating or set at a voltage approximately one half of the HV. The unselected bit lines and source lines of unselected cells in a selected byte are coupled to ground, depending on the desired programmed pattern. The remaining unselected cells in the selected SWL are all coupled to ground. It prevents the FN tunneling effect within the predetermined program time so that no reverse FN tunneling effect may occur and the data of unselected cells can remain unchanged. Meanwhile, the remaining unselected cells in the unselected SWL are all coupled to HV2. HV2 are preferably set to a voltage value around one half of HV1 such as +8.0V to prevent the FN tunneling effect within the predetermined program time so that no reverse FN tunneling effect may occur and the data of unselected cells can remain unchanged.

With reference to FIG. 3D, a voltage of 0V on the selected word line SWL is applied to the gates of the FTs in the selected byte in the byte-program operation. With the Poly2 gate of the selected FT cell biased at 0V of SWL and the channel region of the selected FTa at around 16.0V from the selected bit line, a reverse FN tunneling effect of byte-program is induced on the tunnel layer between the floating-gate of the selected FTa and the channel region on each of the selected FT cells collectively and simultaneously. The stored electrons in the floating-gates of the selected FT cells are expelled out to the channel regions of the cells. Thus, the Vt of each selected FT cell of a selected byte is decreased to a desired value of 1.0V after a predetermined time of a programmed pulse of about 1 ms.

The binary data of the flash cell would be changed from “1” to “0” for those selected cells in the selected byte after the byte-program operation. For those unselected cells, the stored electrons are not affected and thus the stored data remain unchanged after the program operation. This second step of byte-program in a byte-write operation is also automatically performed by an on-chip state machine following the successful first step of byte-erasure. A program-verify operation is necessary after the byte-program operation. All the SL and BL voltages of unselected cells in the remaining unselected bytes in the selected page or in other unselected pages of the flash array are grounded so that no FN tunneling effect may occur and the data of the unselected cells can remain unchanged. Meanwhile, all the unselected SWL voltages of unselected cells in the remaining unselected page of the flash array are coupled to HV2. HV2 are preferably set to a voltage value around one half of HV1 such as +8.0V to prevent the FN tunneling effect within the predetermined program time so that no reverse FN tunneling effect may occur and the data of unselected cells can remain unchanged.

Each 1T FT cell in the 1T FLOTOX-based flash cell array shown in FIG. 3D comprises of FTa and FTb without a selected transistor ST. Each bit line BLn is connected directly to the drain of FTa and the source of FTb is directly connected to one dedicated source line SLn. Any 16.0V bit line leakage from a selected flash cell due to the FTb punch-through issue would not leak to any adjacent bit lines because there is no common source line. Therefore, as long as the leakage is being controlled to be less than 8V, the program operation on the selected FT cells can be successfully carried out. As a result, similar to the 2T EEPROM array shown in FIG. 2C, the channel length of each FTb transistor in the 1T flash cell shown in FIG. 3D of the present invention can be reduced.

FIG. 3F is a table showing the preferred biased voltage conditions for three key bit-alterable operations of a selected page of a 1T FLOTOX-based flash cell array 600 of FIG. 3D. The three key bit-alterable operations include read, program and erasure performed in unit of a page, and a set of preferred biased voltages for the selected and unselected BLs of BL0-BL7, SLs of SL0-SL7 and WLn is shown. The typical byte-read operation of the 1T flash array in the bit-alterable operation is identical to that in the byte-alterable operation. Therefore, the byte-read operation is not described again. It should be noted that the same biased condition can be used for a page-alterable and block-alterable 1T flash memory according the present invention.

In a typical bit-erasure operation of the 1T flash array, a flexible numbers of cells are selected for a write operation. Only one byte of BL and SL out of a page is selected along with one selected SWL. In this case, only the selected BLn and SLn of the selected byte are coupled to 0V via the bit line decoder and the source line decoder respectively. The remaining unselected BLn and SLn of the selected byte and all BLn and SLn of the unselected bytes in the selected SWL are all coupled to HV2. HV2 are preferably set to a voltage value around one half of HV1 such as +8.0V to prevent the FN tunneling effect within the predetermined erase time of 1 ms. The selected SWL is coupled to HV1 in the range from +15.0V to +17.0V.

With reference to FIG. 3D, a voltage of around 16V is applied on the selected WL. With the gate of the selected FT connected to SWL biased at 16.0V and the channel region of the selected FT at 0V from the selected bit line, the tunneling oxide layer of the FT would induce the FN tunneling effect. The gates of the seven unselected FT transistor of the selected SWL are biased at about 16.0V and the channel regions of the seven unselected FT transistors are biased at HV2 which is about 8.0V, the tunneling oxide voltage would not be high enough to induce the FN tunneling effect. As a result, only the Vt of the selected FT would be increased to a desired erased value of +4.0V to +5.0V along with the unchanged Vt of unselected bits after a predetermined time of a bit-erasure pulse of about 1 ms. This bit-erasure step is automatically performed by an on-chip state machine. Usually a longer erase pulse of 1 ms is used to achieve a high successful rate so that an erase-verify step can be skipped to simplify the logic design of a state machine. All the bit lines and source lines of the unselected cells in the remaining unselected bytes in the selected page are set to HV2 so that no FN tunneling effect can occur and the data of the unselected cells can remain unchanged. All the SWL voltages of unselected cells in the other unselected pages of flash array are grounded so that no FN tunneling effect can occur and the data of the unselected cells can remain unchanged.

In a typical bit-program operation of 1T flash array 600 in FIG. 3D of the present invention, any flexible number of bits out of a selected byte can be selected to perform for data change. The selected SWL is now coupled to a 0V. The number of the selected bit lines out of eight BL0-BL7 is flexible from 1 to 8 and the selected bit lines are coupled to a same HV1 in the range of 15.0V to 17.0V along with the same number of selected source lines of SL0-SL7 set as floating or coupled to a value of HV2, and 0V for the unselected bit lines and source lines. The floating voltage or the HV2 biased voltage for the selected cell is used to prevent the fatal punch-through problem from occurring in the channel region of the FTb. The remaining unselected BLs and SLs in a selected byte are coupled to ground.

With reference to FIG. 3D, a voltage of 0V is applied to the selected WL. With approximately 16.0V of a selected bit line coupled to the channel region of a selected FT, and the gate of the selected FT connected to the selected SWL biased at 0V, a reverse FN tunneling effect is induced in the selected FT. The stored electrons in the floating-gate of the selected FT cell are expelled out to the channel region of the cell. Therefore, the Vt of any selected bit in a selected byte can be flexibly programmed to a desired value of +1.0V after a predetermined time about 1 ms.

The binary data of the flash array would be changed from “1” to “0” after the bit-program operation for those selected flash cells. For those unselected cells, the stored electrons are not affected and thus the stored data remain unchanged after the bit-program operation. Similarly, this second-step of bit-program in a bit-write operation is also automatically performed by an on-chip state machine following the successful first step of bit-erasure. A program-verify step is necessary after the bit-program operation. All the voltages of SWL, BLs, and SLs of unselected cells in the remaining unselected bytes in the selected page of the flash array of the present invention are grounded so that no reverse FN tunneling effect may occur and the data of unselected cells can remain unchanged. The remaining unselected cells in the unselected SWL are all coupled to HV2. HV2 are preferably set to a voltage value around one half of HV1 such as +8.0V to prevent the FN tunneling effect within the predetermined program time so that no reverse FN tunneling effect may occur and the data of unselected cells can remain unchanged.

With the 1T flash array shown in FIG. 3D along with the preferred biased voltages set for the selected BLn and SLn of the present invention, the punch-through issue in a bit-program operation can be solved. As shown in FIG. 3F, in the bit-alterable program operation of the present invention, only a maximum of about 8V drop is coupled across the channel of the selected FTb rather than 16V, and thus the punch-through effect has been greatly reduced. In the case of a floating SL of the selected cell with a preferable shorter channel length of the FTb transistor, the 16.0V BLn would leak to SLn up to about 8V and then be automatically stopped. In either case, the bit-program operation for the flexible number of the selected cells can still be performed successfully. The method of biasing SLn to floating has one advantage that it does not require an 8V HV2 source generator. Thus the charge-pump circuit design for HV can be further simplified and the cell size reduction can be economically achieved in this preferred bit-program operation of the present invention.

The block size of a flash array is usually defined as 1 Mb that covers 1,000 word lines and 1,000 bit lines typically. During the block erasure operation, the cells in the selected block of 1,000 word lines and 1,000 bit lines are being erased collectively and simultaneously. The erase operation of the present invention uses low current FN tunneling effect. Typically, the erasure takes around 1 ms-5 ms for a whole block. Similarly, the program operation also uses the low-current FN tunneling.

Although the erasure size is in unit of block, the program operation is always performed in unit of page for the FLOTOX-based flash array 600 of the present invention shown in FIG. 3D. During read, page program and page erasure operations of the FLOTOX-based flash array, only one word line is being selected. The rest of 1T FLTOX cells in the unselected word lines are coupled at the preferred biased voltage condition of the present invention to avoid the punch-through and disturbance of flash cells during program. For a typical flash program operation, a popular specification is a page program that means a single word line is selected.

The typical block-erasure time for the traditional channel-hot-electron program (CHE-program) 1T NOR flash, which can be programmed in byte or word due to the high 100 uA program current per cell, is very long around 500 ms and has a long-held over-erasure concern. In the traditional 1T NOR flash array, the block-erase operation is to decrease the Vt voltages of all selected cells that may have more than two cells in the selected bit line in the negative voltages below 0V. The negative Vt would result in the bit line leakage and has to be brought back to a positive value after erasure. And because there are almost 1,000 cells in the selected block during the block-erasure, the Vt variation in the 1 million bits is large and hard to be well controlled. In the 1T FLOTOX-based flash array of the present invention, the erased Vt is usually defined to be positive. After the block erasure, the Vt voltages of all cells become positive in the selected word lines and bit lines in the selected block. Therefore, there is no over-erase concern at all so that a much faster fast block erasure speed of 1 ms-5 ms can be carried out in the 1T FLOTOX-based flash array of the present invention.

All the devices of the FLOTOX-based flash and EEPROM cell arrays and peripheral area HV NMOS devices in the present invention are similarly formed on the top of P-substrate without any triple p-well and a deep N-well. The 2T FLOTOX-based EEPROM cell array is used for the small byte-alterable non-volatile data memory with 1M high P/E endurance cycles, while the 1T FLOTOX-based flash array is used to store the block-alterable code with 100K P/E cycles. The channel lengths of ST and FTb of the 2T EEPROM cells and FTb of the 1T flash cells of the present invention are preferably made smaller than the traditional one for cell size reduction due to less leakage concern during a FN channel-program operation.

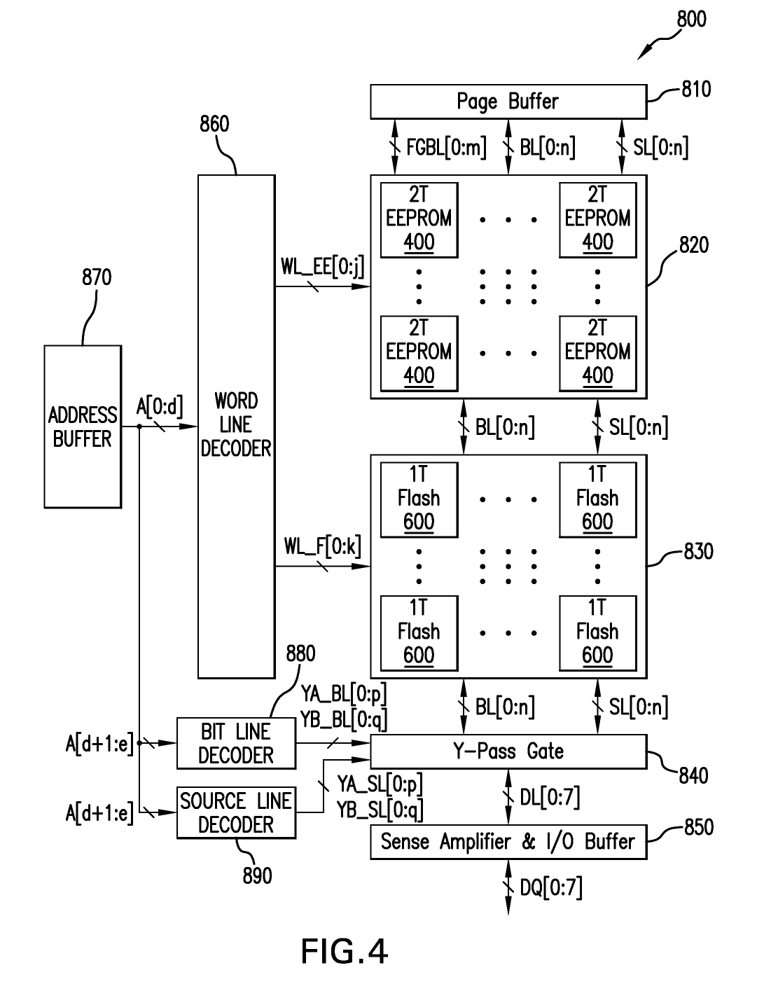

According to the present invention, the 1T FLOTOX-based flash array and 2T FLOTOX-based EEPROM cell array can be manufactured on a same chip as a combo NMV array shown in FIG. 4. The combo NMV array which comprises 1T FLOTOX-based flash array 830 and 2T FLOTOX-based EEPROM array 820 based on the same FLOTOX-based cell structure, cell FN tunneling schemes, and the same manufacturing process. The 1T FLOTOX-based flash array is preferable to have write options of bit-alterable, page-alterable and block-alterable functions. Similarly, the 2T EEPROM array is preferable to have similar options of bit-alterable, byte-alterable and page-alterable functions. The two arrays may share the same address buffers 870, word line decoder 860, bit line decoder 880, source line decoder 890, page buffers 810, Y-pass gate 840, and sense amplifiers and output buffers 850 as well as other control signals such as chip enable (CE) and output enable (OE) control signals and the same clock input.

Although the present invention has been described with reference to the exemplary embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A floating gate tunneling oxide based (FLOTOX-based) non-volatile memory (NVM) array, comprising:
a matrix of a plurality of FLOTOX-based NVM cells arranged in a plurality of rows and columns, each of said FLOTOX-based NVM cells having a control gate, a drain node and a source node;
a plurality of word lines, each word line associated with a row of said FLOTOX-based NVM cells and coupled to the control gates of said FLOTOX-based NVM cells in the associated row;
a plurality of bit lines, each bit line associated with a column of said FLOTOX-based NVM cells and connected to the drain nodes of said FLOTOX-based NVM cells in the associated column, said bit lines being laid out perpendicular to said word lines; and
a plurality of source lines, each source line associated with a column of said FLOTOX-based NVM cells and connected to the source nodes of said FLOTOX-based NVM cells in the associated column;
wherein the source nodes of a plurality of said FLOTOX-based NVM cells in a row are not connected together and there are no common lines laid out in parallel with the word line associated with the row to connect the source nodes of said FLOTOX-based NVM cells in the row.

2. The FLOTOX-based NVM array of claim 1, wherein the source lines and the bit lines are metal lines placed in parallel, and the number of the source lines is identical to the number of the bit lines.

3. The FLOTOX-based NVM array of claim 1, wherein each FLOTOX-based NVM cell is a two-transistor FLOTOX-based EEPROM cell comprising a select transistor having a gate connected to the word line which is coupled to the FLOTOX-based NVM cell and a floating-gate transistor having a drain merged with a source of the select transistor, and wherein the source of the select transistor, a drain of the floating-gate transistor and a control gate of the floating-gate transistor form the source node, the drain node and the control gate of the FLOTOX-based NVM cell respectively.

4. The FLOTOX-based NVM array of claim 3, further comprising:
a gated byte line associated with a plurality of bytes of said FLOTOX-based NVM cells, each byte comprising a number of said FLOTOX-based NVM cells in a same row; and
a plurality of byte-selecting transistors, each byte-selecting transistor associated with a byte of said FLOTOX-based NVM cells and each byte-selecting transistor having a gate connected the word line associated with the FLOTOX-based NVM cells in the byte, a drain connected to the gated byte line associated with the byte, and a source connected to the control gates of the FLOTOX-based NVM cells in the byte.

5. The FLOTOX-based NVM array of claim 4, further comprising a byte-erasure operation for erasing a selected byte of said FLOTOX-based NVM cells by the following bias conditions:
connecting the source lines and the bit lines associated with the FLOTOX-based NVM cells in the selected byte to 0V; and
connecting the gated byte line associated with the selected byte and the word line associated with the FLOTOX-based NVM cells in the selected byte to a high voltage approximately in a range from 15.0V to 17.0V.

6. The FLOTOX-based NVM array of claim 4, further comprising a byte-program operation for programming a selected byte of said FLOTOX-based NVM cells with selected one or more FLOTOX-based NVM cells to be programmed by the following bias conditions:
connecting the word line associated with the FLOTOX-based NVM cells in the selected byte and the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the gated byte line associated with the selected byte, and the bit lines and the source lines associated with remaining unselected FLOTOX-based NVM cells of the selected byte to 0V.

7. The FLOTOX-based NVM array of claim 4, further comprising a bit-erasure operation for erasing a selected byte of said FLOTOX-based NVM cells with selected one or more FLOTOX-based NVM cells to be erased by the following bias conditions:
connecting the gated byte line associated with the selected byte and the word line associated with the FLOTOX-based NVM cells in the selected byte to a first high voltage approximately in a range from 15.0V to 17.0V;
connecting the bit lines and the source lines associated with the selected one or more FLOTOX-based NVM cells of the selected byte to 0V; and
connecting the bit lines and the source lines associated with remaining unselected FLOTOX-based NVM cells of the selected byte to a second high voltage which is approximately one half of the first high voltage.

8. The FLOTOX-based NVM array of claim 4, further comprising a bit-program operation for programming a selected byte of said FLOTOX-based NVM cells with selected one or more FLOTOX-based NVM cells to be programmed by the following bias conditions:
connecting the word line associated with the FLOTOX-based NVM cells in the selected byte and the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the gated byte line associated with the selected byte, and the bit lines and the source lines associated with remaining unselected FLOTOX-based NVM cells of the selected byte to 0V.

9. The FLOTOX-based NVM array of claim 1, wherein each FLOTOX-based NVM cell is a one-transistor FLOTOX-based flash cell comprising a floating-gate transistor having a source, a drain and a control gate as the source node, the drain node and the control gate of the FLOTOX-based NVM cell respectively.

10. The FLOTOX-based NVM array of claim 9, wherein each word line is connected to the control gates of the one-transistor FLOTOX-based flash cells in the associated row.

11. The FLOTOX-based NVM array of claim 10, further comprising a byte-erasure operation for erasing a selected byte of said FLOTOX-based NVM cells, each byte comprising a number of said FLOTOX-based NVM cells in a same row, by the following bias conditions:
connecting the source lines and the bit lines associated with the FLOTOX-based NVM cells in the selected byte to 0V; and
connecting the word line associated with the FLOTOX-based NVM cells in the selected byte to a high voltage approximately in a range from 15.0V to 17.0V.

12. The FLOTOX-based NVM array of claim 10, further comprising a byte-program operation for programming a selected byte of said FLOTOX-based NVM cells with selected one or more FLOTOX-based NVM cells to be programmed by the following bias conditions:
connecting the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the word line associated with the FLOTOX-based NVM cells in the selected byte, and the bit lines and the source lines associated with remaining unselected FLOTOX-based NVM cells of the selected byte to 0V.

13. The FLOTOX-based NVM array of claim 10, further comprising a bit-erasure operation for erasing a selected byte of said FLOTOX-based NVM cells with selected one or more FLOTOX-based NVM cells to be erased by the following bias conditions:
connecting the word line associated with the FLOTOX-based NVM cells in the selected byte to a first high voltage approximately in a range from 15.0V to 17.0V;
connecting the bit lines and the source lines associated with the selected one or more FLOTOX-based NVM cells of the selected byte to 0V; and
connecting the bit lines and the source lines associated with remaining unselected FLOTOX-based NVM cells of the selected byte to a second high voltage which is approximately one half of the first high voltage.

14. The FLOTOX-based NVM array of claim 10, further comprising a bit-program operation for programming a selected byte of said FLOTOX-based NVM cells with selected one or more FLOTOX-based NVM cells to be programmed by the following bias conditions:
connecting the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the word line associated with the FLOTOX-based NVM cells in the selected byte and the bit lines and the source lines associated with remaining unselected FLOTOX-based NVM cells of the selected byte to 0V.

15. A method of operating a floating gate tunneling oxide based (FLOTOX-based) non-volatile memory (NVM) device, comprising:
providing a FLOTOX-based NVM array comprising:
a matrix of a plurality of FLOTOX-based NVM cells arranged in a plurality of rows and columns, each of said FLOTOX-based NVM cells having a control gate, a drain node and a source node;
a plurality of word lines, each word line associated with a row of said FLOTOX-based NVM cells and coupled to the control gates of said FLOTOX-based NVM cells in the associated row;
a plurality of bit lines, each bit line associated with a column of said FLOTOX-based NVM cells and connected to the drain nodes of said FLOTOX-based NVM cells in the associated column, said bit lines being laid out perpendicular to said word lines; and
a plurality of source lines, each source line associated with a column of said FLOTOX-based NVM cells and connected to the source nodes of said FLOTOX-based NVM cells in the associated column;
wherein the source nodes of a plurality of said FLOTOX-based NVM cells in a row are not connected together and there are no common lines laid out in parallel with the word line associated with the row to connect the source nodes of said FLOTOX-based NVM cells in the row;
providing a byte-erasure operation and bias conditions of the associated word lines, bit lines, and source lines for erasing a selected byte comprising a number of said FLOTOX-based NVM cells in a same row based on Fowler-Nordheim (FN) tunneling effect; and
providing a byte-program operation and bias conditions of the associated word lines, bit lines, and source lines for programming a selected byte comprising a number of said FLOTOX-based NVM cells in a same row based on reverse FN tunneling effect.

16. The method of claim 15, wherein the source lines and the bit lines are metal lines placed in parallel, and the number of the source lines is identical to the number of the bit lines.

17. The method of claim 15, wherein each FLOTOX-based NVM cell is a two-transistor FLOTOX-based EEPROM cell comprising a select transistor having a gate connected to the word line which is coupled to the FLOTOX-based NVM cell and a floating-gate transistor having a drain merged with a source of the select transistor, and wherein the source of the select transistor, a drain of the floating-gate transistor and a control gate of the floating-gate transistor form the source node, the drain node and the control gate of the FLOTOX-based NVM cell respectively.

18. The method of claim 17, wherein said FLOTOX-based NVM array further comprises:
a gated byte line associated with a plurality of bytes of said FLOTOX-based NVM cells, each byte comprising a number of said FLOTOX-based NVM cells in a same row; and
a plurality of byte-selecting transistors, each byte-selecting transistor associated with a byte of said FLOTOX-based NVM cells and each byte-selecting transistor having a gate connected the word line associated with the FLOTOX-based NVM cells in the byte, a drain connected to the gated byte line associated with the byte, and a source connected to the control gates of the FLOTOX-based NVM cells in the byte.

19. The method of claim 18, wherein the bias conditions for the byte-erasure operation for erasing a selected byte are provided by:
connecting the source lines and the bit lines associated with the FLOTOX-based NVM cells in the selected byte to 0V; and
connecting the gated byte line associated with the selected byte and the word line associated with the FLOTOX-based NVM cells in the selected byte to a high voltage approximately in a range from 15.0V to 17.0V.

20. The method of claim 18, wherein the bias conditions for the byte-program operation for programming a selected byte with selected one or more FLOTOX-based NVM cells to be programmed are provided by:
connecting the word line associated with the FLOTOX-based NVM cells in the selected byte and the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the gated byte line associated with the selected byte, and the bit lines and the source lines associated with remaining unselected FLOTOX-based NVM cells of the selected byte to 0V.

21. The method of claim 18, further providing a bit-erasure operation for erasing a selected byte of said FLOTOX-based NVM cells with selected one or more FLOTOX-based NVM cells to be erased by the following bias conditions:
connecting the gated byte line associated with the selected byte and the word line associated with the FLOTOX-based NVM cells in the selected byte to a first high voltage approximately in a range from 15.0V to 17.0V;
connecting the bit lines and the source lines associated with the selected one or more FLOTOX-based NVM cells of the selected byte to 0V; and
connecting the bit lines and the source lines associated with remaining unselected FLOTOX-based NVM cells of the selected byte to a second high voltage which is approximately one half of the first high voltage.

22. The method of claim 18, further providing a bit-program operation for programming a selected byte of said FLOTOX-based NVM cells with selected one or more FLOTOX-based NVM cells to be programmed by the following bias conditions:
connecting the word line associated with the FLOTOX-based NVM cells in the selected byte and the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the gated byte line associated with the selected byte, and the bit lines and the source lines associated with remaining unselected FLOTOX-based NVM cells of the selected byte to 0V.

23. The method of claim 15, wherein each FLOTOX-based NVM cell is a one-transistor FLOTOX-based flash cell comprising a floating-gate transistor having a source, a drain and a control gate as the source node, the drain node and the control gate of the FLOTOX-based NVM cell respectively.

24. The method of claim 23, wherein each word line is connected to the control gates of the one-transistor FLOTOX-based flash cells in the associated row.

25. The method of claim 24, wherein the bias conditions for the byte-erasure operation for erasing a selected byte are provided by:
connecting the source lines and the bit lines associated with the FLOTOX-based NVM cells in the selected byte to 0V; and
connecting the word line associated with the FLOTOX-based NVM cells in the selected byte to a high voltage approximately in a range from 15.0V to 17.0V.

26. The method of claim 24, wherein the bias conditions for the byte-program operation for programming a selected byte with selected one or more FLOTOX-based NVM cells to be programmed are provided by:
connecting the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the word line associated with the FLOTOX-based NVM cells in the selected byte, and the bit lines and the source lines associated with remaining unselected FLOTOX-based NVM cells of the selected byte to 0V.

27. The method of claim 24, further providing a bit-erasure operation for erasing a selected byte of said FLOTOX-based NVM cells with selected one or more FLOTOX-based NVM cells to be erased by the following bias conditions:
connecting the word line associated with the FLOTOX-based NVM cells in the selected byte to a first high voltage approximately in a range from 15.0V to 17.0V;
connecting the bit lines and the source lines associated with the selected one or more FLOTOX-based NVM cells of the selected byte to 0V; and
connecting the bit lines and the source lines associated with remaining unselected FLOTOX-based NVM cells of the selected byte to a second high voltage which is approximately one half of the first high voltage.

28. The method of claim 24, further providing a bit-program operation for programming a selected byte of said FLOTOX-based NVM cells with selected one or more FLOTOX-based NVM cells to be programmed by the following bias conditions:
connecting the bit lines associated with the selected one or more FLOTOX-based NVM cells of the selected byte to a first high voltage approximately in a range from 15.0V to 17.0V;
connecting the source lines associated with the selected one or more FLOTOX-based NVM cells of the selected byte to a second high voltage which is set to either floating or approximately one half of the first high voltage; and
connecting the word line associated with the FLOTOX-based NVM cells in the selected byte and the bit lines and the source lines associated with remaining unselected FLOTOX-based NVM cells of the selected byte to 0V.

29. A one-transistor floating gate tunneling oxide based (FLOTOX-based) flash cell for providing block-erasure and page program operations, comprising a floating-gate transistor having a drain connected to a bit line, a control gate connected to a word line, and a source connected to a source line;
wherein the bit line and the source line are parallel and the word line is perpendicular to the bit line;
wherein during an erasure operation of the one-transistor FLOTOX-based flash cell, both the bit line and the source line are connected to a 0V and the word line is connected to a first high voltage; and
wherein during a program operation of the one-transistor FLOTOX-based flash cell, the bit line is connected to the first high voltage, the source line is connected to a second high voltage, and the word line is connected to 0V.

30. The one-transistor FLOTOX-based flash cell of claim 29, wherein the bit line and the source line are metal lines placed in parallel.

31. The one-transistor FLOTOX-based flash cell of claim 29, wherein the first high voltage is approximately in a range from +15.0V to +17.0V, and the second high voltage is approximately one-half of the first high voltage.

32. The one-transistor FLOTOX-based flash cell of claim 29, wherein the first high voltage is approximately in a range from +15.0V to +17.0V, and the second high voltage is floating.

33. The one-transistor FLOTOX-based flash cell of claim 29, wherein both the bit line and the source line are connected to 0V if a byte containing the one-transistor FLOTOX-based flash cell is selected for programming but a bit associated with the one-transistor FLOTOX-based flash cell is not selected for programming.

34. The one-transistor FLOTOX-based flash cell of claim 29, wherein both the bit line and the source line are connected to the second high voltage if a byte containing the one-transistor FLOTOX-based flash cell is selected for erasure but a bit associated with the one-transistor FLOTOX-based flash cell is not selected for erasure.

35. A floating gate tunneling oxide based (FLOTOX-based) non-volatile memory (NVM) device comprising at least one one-transistor FLOTOX-based flash cell array and at least one two-transistor FLOTOX-based EEPROM cell array, wherein the one-transistor FLOTOX-based flash cell array comprising:
a matrix of a plurality of one-transistor FLOTOX-based flash cells arranged in a plurality of rows and columns, each of said one-transistor FLOTOX-based flash cells having a control gate, a drain node and a source node;
a plurality of word lines, each word line associated with a row of said one-transistor FLOTOX-based flash cells and coupled to the control gates of said one-transistor FLOTOX-based flash cells in the associated row;
a plurality of bit lines, each bit line associated with a column of said one-transistor FLOTOX-based flash cells and connected to the drain nodes of said one-transistor FLOTOX-based flash cells in the associated column, said bit lines being laid out perpendicular to said word lines; and
a plurality of source lines, each source line associated with a column of said one-transistor FLOTOX-based flash cells and connected to the source nodes of said one-transistor FLOTOX-based flash cells in the associated column; and
the two-transistor FLOTOX-based EEPROM cell array comprising:
a matrix of a plurality of two-transistor FLOTOX-based EEPROM cells arranged in a plurality of rows and columns, each two-transistor FLOTOX-based EEPROM cell comprising a select transistor having a gate and a floating-gate transistor having a drain merged with a source of said select transistor, and wherein the source of the select transistor, a drain of the floating-gate transistor and a control gate of the floating-gate transistor serve as a source node, a drain node and a control gate of the two-transistor FLOTOX-based EEPROM respectively;
a plurality of word lines, each word line associated with a row of said two-transistor FLOTOX-based EEPROM cells and coupled to the control gates of said two-transistor FLOTOX-based EEPROM cells in the associated row;
a plurality of bit lines, each bit line associated with a column of said two-transistor FLOTOX-based EEPROM cells and connected to the drain nodes of said two-transistor FLOTOX-based EEPROM cells in the associated column, said bit lines being laid out perpendicular to said word lines;
a plurality of source lines, each source line associated with a column of said two-transistor FLOTOX-based EEPROM cells and connected to the source nodes of said two-transistor FLOTOX-based EEPROM cells in the associated column;
a gated byte line associated with a plurality of bytes of said two-transistor FLOTOX-based EEPROM cells, each byte comprising a number of said two-transistor FLOTOX-based EEPROM cells in a same row; and
a plurality of byte-selecting transistors, each byte-selecting transistor associated with a byte of said two-transistor FLOTOX-based EEPROM cells and each byte-selecting transistor having a gate connected the word line associated with two-transistor FLOTOX-based EEPROM cells in the byte, a drain connected to the gated byte line associated with the byte, and a source connected to the control gates of the two-transistor FLOTOX-based EEPROM cells in the byte;
wherein the source nodes of a plurality of said one-transistor FLOTOX-based flash cells or said two-transistor FLOTOX-based EEPROM cells in a row are not connected together and there are no common lines laid out in parallel with the word line associated with the row to connect the source nodes of said one-transistor FLOTOX-based flash cells or said two-transistor FLOTOX-based EEPROM cells in a row.

36. The FLOTOX-based NVM device of claim 35, further comprising address buffers, word line decoders, bit line decoders, source line decoders, page buffers, sense amplifiers, output buffers and control signals shared by the one-transistor FLOTOX-based flash cell array and the two-transistor FLOTOX-based EEPROM cell array.
